(19) United States
(12) Patent Application Publication
(10) Pub. No.: US 2026/0160549 A1
(43) Pub. Date: Jun. 11, 2026

(54) POWER MODULE MANUFACTURING SYSTEM AND JIG SUPPLYING METHOD THEREOF

(71) Applicant: HYUNDAI MOBIS CO., LTD., Seoul (KR)

(72) Inventors: Ji Hyun PARK, Yongin-si (KR); Hong Seok YANG, Yongin-si (KR)

(73) Assignee: HYUNDAI MOBIS CO., LTD., Seoul (KR)

(21) Appl. No.: 19/332,852

(22) Filed: Sep. 18, 2025

(30) Foreign Application Priority Data
Dec. 10, 2024 (KR) 10-2024-0182342

(51) Int. Cl. G01B 21/08; H05K 13/00; H05K 13/08; H02M 7/00

(52) U.S. Cl. CPC G01B 21/08; H05K 13/0069; H05K 13/083; H02M 7/003

(57) ABSTRACT

Proposed are a power module manufacturing system and a jig supplying method thereof, which is capable of supplying a normal jig and improving efficiency of a power module production. The power module manufacturing system according to an exemplary embodiment of the present disclosure includes an analyzer for calculating abnormality index information per jig based on a normality determination thickness measured with respect to a power module previously manufactured using a jig, and a process controller for receiving jig information corresponding to information about the jig supplied for manufacturing a new power module, for determining an abnormality index corresponding to the jig information based on the abnormality index information per jig, and for supplying the jig corresponding to the jig information to a manufacturing process of the new power module when the abnormality index satisfies a preset supply permitting condition.

### CROSS REFERENCE TO RELATED APPLICATION

The present application claims priority to Korean Patent Application No. 10-2024-0182342, filed on December 10, 2024, the entire contents of which are incorporated herein for all purposes by this reference.

### TECHNICAL FIELD

The present disclosure relates to a power module manufacturing technology and, more particularly, to a power module manufacturing system and a jig supplying method thereof, which is capable of supplying a normal jig and improving efficiency of a power module production.

### BACKGROUND

Power modules are used in various power and electronic fields. For example, inverters used to drive eco-friendly vehicles (e.g., hybrid vehicles, electric vehicles, etc.) are provided with multiple power modules.

In order to manufacture power modules, a bonding process is required to electrically and physically connect a semiconductor chip (an element) to an insulating substrate to which electrodes are attached. The bonding process mainly uses the soldering process that utilizes the melting/solidification phenomenon of solder, which is an adhesive metal, in order to connect semiconductor chips and substrates.

In general, the soldering is generally performed using a jig for fixing the position of each component, such as a semiconductor chip, so it is very important to provide normal jigs in the manufacturing process of the power modules.

However, since defective jigs are currently isolated after recognizing the defect of the jig through a simple rule based on the number of defect occurrences, the power modules manufactured by the defective jigs are discarded, thereby reducing the production efficiency and the production yield rate of the power modules.

Therefore, in order to increase the production efficiency and the production yield rate of the power modules, it is necessary to provide a method for providing normal jigs to the manufacturing process of the power module.

The matters described as the background technology above are only intended to enhance understanding of the background of the present disclosure, and should not be accepted as acknowledging correspondence to the prior art already known to those skilled in the art.

### SUMMARY

A technical task of an exemplary embodiment disclosed in the present specification is to provide a power module manufacturing system and a jig supplying method thereof, which prevents a defective jig in advance from being supplied to a manufacturing process of a power module and improves the production efficiency and the production yield rate of the power module.

A technical task of an exemplary embodiment in the present disclosure is to provide a power module manufacturing system and a jig supplying method thereof, which prevents supplying defective jigs by training with normality determination data selected based on the thickness measured at a preset position of the manufactured power module, by calculating an abnormality index of a jig for each vehicle type, and by determining whether to supply jigs based on the calculated abnormality index.

The technical tasks to be achieved by the present disclosure are not limited to the technical tasks mentioned above, and other technical tasks not mentioned may be clearly understood by those skilled in the art to which the present disclosure belongs from the following description.

A power module manufacturing system according to an exemplary embodiment of the present disclosure for achieving the objectives includes an analyzer for calculating abnormality index information per jig based on a normality determination thickness measured with respect to a power module previously manufactured using a jig, and a process controller for receiving jig information corresponding to information about the jig supplied for manufacturing a new power module, for determining an abnormality index corresponding to the jig information based on the abnormality index information per jig, and for supplying the jig corresponding to the jig information to a manufacturing process of the new power module when the abnormality index satisfies a preset supply permitting condition.

According to an exemplary embodiment of the present disclosure, the analyzer may generate a normality determination thickness-jig information set by matching the jig information used to manufacture the previously manufactured power module with the normality determination thickness, and may calculate the abnormality index information per jig based on the normality determination thickness-jig information set.

According to an exemplary embodiment of the present disclosure, the analyzer may calculate the abnormality index information per jig based on a training with the normality determination thickness.

According to an exemplary embodiment of the present disclosure, the process controller may determine that the supply permitting condition is satisfied when the abnormality index is less than or equal to a preset the abnormality threshold value.

According to an exemplary embodiment of the present disclosure, the abnormality index information per jig may be sorted in descending or ascending order, and the process controller may determine that the supply permitting condition is satisfied when the abnormality index corresponding to the jig information is determined to be within a preset rank.

A jig supplying method of a power module manufacturing system according to an exemplary embodiment of the present disclosure includes calculating abnormality index information per jig based on a normality determination thickness measured with respect to a power module previously manufactured using a jig, receiving jig information corresponding to information about the jig supplied for manufacturing a new power module, determining an abnormality index corresponding to the jig information based on the abnormality index information per jig, and supplying the jig corresponding to the jig information to a manufacturing process of the new power module when the abnormality index satisfies a preset supply permitting condition.

According to an exemplary embodiment of the present disclosure, the calculating may include generating a normality determination thickness-jig information set by matching the jig information used to manufacture the previously manufactured power module with the normality determination thickness, and calculating the abnormality index information per jig based on the normality determination thickness-jig information set.

According to an exemplary embodiment of the present disclosure, the calculating may include calculating the abnormality index information per jig based on a training with the normality determination thickness.

According to an exemplary embodiment of the present disclosure, the supply permitting condition may be satisfied in the supplying when the abnormality index is less than or equal to a preset the abnormality threshold value.

According to an exemplary embodiment of the present disclosure, the abnormality index information per jig may be sorted in descending or ascending order, and the supply permitting condition may be satisfied in the supplying when the abnormality index is within a preset rank.

Specific matters according to various examples of the present disclosure other than the means for solving the tasks mentioned above are included in the following description and drawings.

According to an exemplary embodiment of the present disclosure, it is possible to prevent a defective jig in advance from being supplied to a manufacturing process of a power module since whether to supply a jig is determined based on an abnormality index calculated with respect to the jig.

By preventing a defective jig in advance from being supplied to a manufacturing process of a power module, it is possible to reduce the cost of discarding defective power modules, and to increase the production efficiency and the production yield rate of the power modules.

According to an exemplary embodiment of the present disclosure, it is possible to automate a jig supply, thereby reducing the production manpower and increasing the system operation rate.

The effects obtainable by the present disclosure are not limited to the effects mentioned above, and other effects not mentioned can be clearly understood by those skilled in the art to which the present disclosure belongs from the description below.

### BRIEF DESCRIPTION OF THE DRAWINGS

The drawings attached below may be intended to help understanding of exemplary embodiments of the present disclosure and provide the exemplary embodiments with a detailed description. However, the technical features of the present exemplary embodiment may not be limited to a specific drawing, and the features disclosed in each drawing may be combined with each other to be configured as a new exemplary embodiment.

FIG. 1 is a view showing a configuration of a power module manufacturing system according to an exemplary embodiment of the present disclosure.

FIG. 2 is a view illustrating a jig supplying method of a power module manufacturing system according to an exemplary embodiment of the present disclosure.

FIG. 3 is a view illustrating a method of calculating an abnormality index per jig in a power module manufacturing system according to an exemplary embodiment of the present disclosure.

### DETAILED DESCRIPTION OF THE DISCLOSURE

In describing an exemplary embodiment disclosed in the present specification, the detailed description thereof will be omitted when it is determined that a detailed description of the related known technology may obscure the gist of the exemplary embodiment disclosed in the present specification. In addition, the accompanying drawings may be only intended to facilitate an easy understanding of the exemplary embodiment disclosed in the present specification, and the technical idea disclosed in the present specification may not be limited by the accompanying drawings, and should be understood to include all modifications, equivalents, or substitutes included in the spirit and technical scope of the present disclosure.

Terms including ordinal numbers, such as first and second, may be used to describe various components, but the components may not be limited by such terms. The terms may be used only for the purpose of distinguishing one component from another component.

Singular expressions may include plural expressions unless the context clearly indicates otherwise.

In the present specification, terms such as "include" or "have" may be intended to specify the presence of features, numbers, steps, operations, components, parts, or combinations thereof described in the specification, and may not exclude in advance the presence or addition of one or more other features, numbers, steps, operations, components, parts, or combinations thereof.

The suffixes "module" and "unit" for components used in the following description may be assigned or used interchangeably for the convenience of writing the specification, and may not have distinct meanings or roles by themselves.

When it is mentioned that a component is "connected" or "linked" to another component, it should be understood that it is directly connected or linked to that other component, but that there may be other components in between. On the other hand, when it is mentioned that a component is "directly connected" or "directly linked" to another component, it should be understood that there are no other components in between.

Hereinafter, exemplary embodiments disclosed in the present specification will be described in detail with reference to the accompanying drawings, but the same or similar components will be assigned the same reference numbers regardless of the drawing symbols, and redundant descriptions thereof will be omitted.

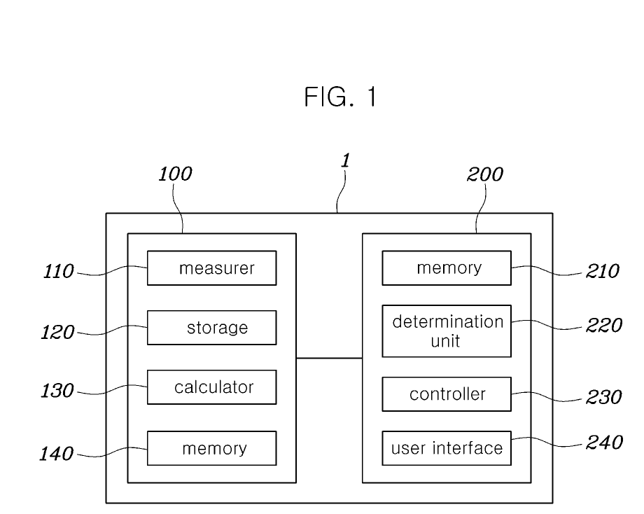

FIG. 1 is a view showing a configuration of a power module manufacturing system 1 according to an exemplary embodiment of the present disclosure.

The power module manufacturing system 1 according to an exemplary embodiment of the present disclosure may be a system for manufacturing a power module constituting an inverter of a vehicle, and the application field of the present disclosure may not be limited to the vehicle field.

The power module manufacturing system 1 according to an exemplary embodiment of the present disclosure may determine whether to supply a jig used for manufacturing the power module and, based on the determination, may supply the jig to the manufacturing process of the power module or recommend another jig.

Referring to FIG. 1, the power module manufacturing system 1 may include an analyzer 100 and a process controller 200, and the configuration of the power module manufacturing system 1 may not be limited thereto.

According to an exemplary embodiment, the analyzer 100 may calculate an abnormality index per jig based on normality determination data selected based on a thickness measured at a preset position of the manufactured power module.

There may be multiple jigs per vehicle model, and each jig may be assigned a lot number. According to an exemplary embodiment, the analyzer 100 may calculate the abnormality index for each of multiple jigs, and may match the lot number and the abnormality index for each jig for the management.

When supplied to the manufacturing process of the power module, the jig may be used to manufacture the plurality of power modules. According to an exemplary embodiment, the analyzer 100 may measure the thickness with respect to each of the plurality of manufactured power modules.

One jig may be used multiple times in the manufacture of the power module within a certain period of time. According to an exemplary embodiment, when the jig is used multiple times within a certain period of time, the analyzer 100 may calculate the abnormality index each time and average the calculated abnormality index.

According to an exemplary embodiment, the analyzer 100 may include a measurer 110, a storage 120, a calculator 130, and a memory 140, and the configuration of the analyzer 100 may not be limited thereto.

The measurer 110 may measure the thickness of the manufactured power module and store the thickness data in the storage 120.

For example, the measurer 110 may measure the thickness of the plurality of power modules manufactured by one jig. For example, the measurer 110 may measure the thickness at a plurality of preset positions with respect to one power module. For example, the thickness may mean a distance between an upper surface of the power module and a lower surface of the power module.

According to an exemplary embodiment, the measurer 110 may have a reference range per position for the normality determination with respect to the thickness of the power module, and compare the thickness measured for the power module with the reference range to store in the storage 120 the thickness data for the power module whose thickness is within the reference range (i.e., determined to be normal).

According to an exemplary embodiment, the measurer 110 may match the thickness data with the lot number and store the same in the storage 120.

For example, the measurer 110 may measure the thickness of the power module based on the vision inspection, and the method of measuring the thickness of the power module may not be limited thereto. For example, various methods such as ultrasonic inspection may be used to measure the thickness of the power module.

The calculator 130 may be trained with the thickness data stored in the storage 120 and calculate the abnormality index per jig.

For example, the calculator 130 may be trained with the thickness data based on an unsupervised learning algorithm. For example, the calculator 130 may be trained with the thickness data based on a Gaussian mixture model (GMM), and the learning method of the calculator 130 may not be limited thereto.

For example, a GMM-based calculator 130 may model the thickness data as a Gaussian distribution, extract an average and covariance from the Gaussian distribution, calculate a Mahalanobis distance with respect to the thickness data based on the average and covariance, and calculate the abnormality index based on the Mahalanobis distance.

According to an exemplary embodiment, when the corresponding jig is supplied to the manufacturing process of the power module in multiple times within a certain period of time, the calculator 130 may provide the average of the abnormality indexes calculated each time to the process controller 200.

In this way, the calculator 130 may provide the process controller 200 with the abnormality index for the jig one time supplied to the manufacturing process of the power module within a certain period of time, and provide the process controller 200 with the average of the abnormality indexes for the jig multiple times supplied to the manufacturing process of the power module within a certain period of time.

Hereinafter, the abnormality index calculated for the one-time supplied jig and the average of the abnormality indexes calculated for the multiple-times supplied jig may be referred to as abnormality index information.

The memory 140 may store algorithms, data, and the like for the operation of the analyzer 100.

For example, the storage 120 and the memory 140 may be implemented as at least one of storage media (or recording media) such as a flash memory, a hard disk, a secure digital card (SD card), a random access memory (RAM), a static random access memory (SRAM), a read-only memory (ROM), a programmable read-only memory (PROM), an electrically erasable and programmable ROM (EEPROM), an erasable and programmable ROM (EPROM), a register, a removable disk, and a web storage.

For example, the measurer 110 and the calculator 130 may include at least one processor to perform an operation. For example, the measurer 110 and the calculator 130 may be implemented by one processor. For example, the processor may be a hardware-implemented data processing device having a circuit with a physical structure for executing desired operations. For example, the desired operations may include codes or instructions included in the program. For example, the hardware-implemented data processing device may include a microprocessor, a central processing unit, a processor core, a multi-core processor, a multiprocessor, an application-specific integrated circuit (ASIC), and a field programmable gate array (FPGA).

According to an exemplary embodiment, the process controller 200 may receive jig information (the supplying jig information) that is supplied for manufacturing the power module, and may determine whether to supply the corresponding jig based on the abnormality index information per jig calculated by the calculator 130.

For example, the jig information may include the lot number of the jig.

According to an exemplary embodiment, the process controller 200 may determine the abnormality index information of the corresponding jig based on the jig information, the lot number. For example, the process controller 200 may determine the abnormality index corresponding to the index information based on the jig information and the abnormality index information per jig.

According to an exemplary embodiment, the process controller 200 may determine whether the abnormality index determined based on the index information satisfies a preset supply permitting condition and, based on the determination result, may determine whether to supply the corresponding jig.

According to an exemplary embodiment, the process controller 200 may include a memory 210, a determination unit 220, a controller 230, and a user interface 240, and the configuration of the process controller 200 may not be limited thereto.

The memory 210 may store algorithms, data, and the like for the operation of the process controller 200. The memory 210 may store the abnormality index information per jig provided from the analyzer 100. For example, the abnormality index information per jig may be sorted in descending or ascending order and be stored in the memory 210.

For example, the memory 210 may be implemented as at least one of storage media (or recording media) such as a flash memory, a hard disk, a secure digital card (SD card), a random access memory (RAM), a static random access memory (SRAM), read-only memory (ROM), a programmable read-only memory (PROM), an electrically erasable and programmable ROM (EEPROM), an erasable and programmable ROM (EPROM), a register, a removable disk, and a web storage.

The determination unit 220 may receive the supplying jig information and may determine whether to supply the corresponding jig based on the abnormality index information per jig provided from the analyzer 100.

According to an exemplary embodiment, the determination unit 220 may determine the abnormality index information corresponding to the jig lot number, which is the supplying jig information, may determine whether the abnormality index satisfies the preset supply permitting condition, and based on the determination result, may determine whether to supply the corresponding jig.

For example, when the abnormality index corresponding to the supplying jig information is less than or equal to a preset abnormality threshold value, the determination unit 220 may determine that the supply permitting condition is satisfied, and determine the corresponding jig as a suppliable jig.

For example, when the abnormality index corresponding to the supplying jig information is within a preset rank based on the abnormality index information per jig sorted in descending or ascending order, the determination unit 220 may determine that the supply permitting condition is satisfied, and determine the corresponding jig as a suppliable jig.

According to an exemplary embodiment, when the abnormality index information per jig provided from the analyzer 100 is sorted in descending or ascending order and the abnormality index corresponding to the supplying jig information is within the preset rank, the determination unit 220 may determine that the supply permitting condition is satisfied, and determine the corresponding jig as a suppliable jig.

According to an exemplary embodiment, the determination unit 220 may determine whether the supply is possible for each jig based on the abnormality index corresponding to the supplying jig information, and may provide information on whether the supply is possible for each jig to the controller 230.

For example, the determination unit 220 may match the jig lot number information with the information on whether the supply is possible and may provide the same to the controller 230.

According to an exemplary embodiment, the controller 230 may receive the information on whether the supply is possible for each jig from the determination unit 220, and may control the process facility so that the corresponding jig can be supplied to the power module process based on the information on whether the supply is possible for each jig or may block the supply of the corresponding jig.

For example, the controller 230 may output information on the non-suppliable jig through the user interface 240.

According to an exemplary embodiment, the controller 230 may output suppliable jig information through the user interface 240 in order to recommend the suppliable jig based on the abnormality index information per jig sorted in descending or ascending order.

For example, the determination unit 220 and the controller 230 may include at least one processor to perform an operation. For example, the determination unit 220 and the controller 230 may be implemented by one processor. For example, the processor may be a hardware-implemented data processing device having a circuit with a physical structure for executing desired operations. For example, the desired operations may include codes or instructions included in the program. For example, the hardware-implemented data processing device may include a microprocessor, a central processing unit, a processor core, a multi-core processor, multiprocessor, an application-specific integrated circuit (ASIC), and a field programmable gate array (FPGA).

The user interface 240 may output information provided from the controller 230. For example, the user interface 240 may include a display module. For example, the display module may include at least one of a liquid crystal display (LCD), a thin film transistor-liquid crystal display (TFT LCD), an organic light-emitting diode (OLED), a flexible display, and a 3D display.

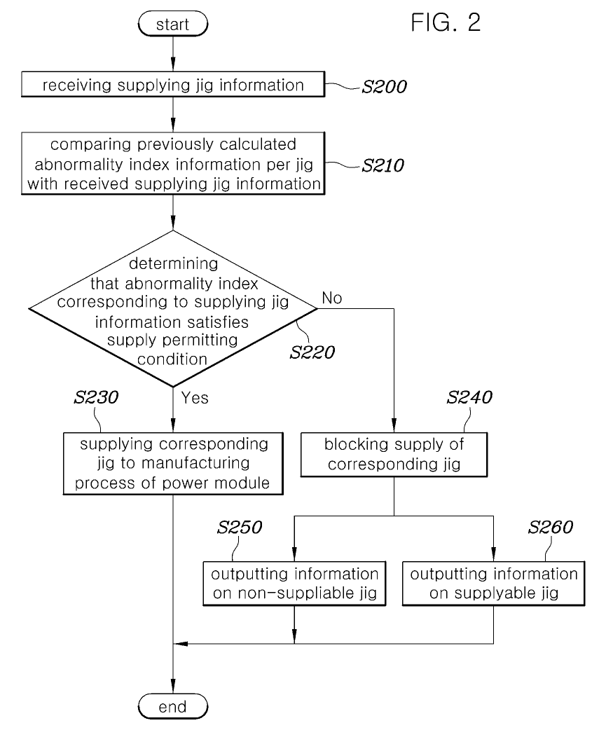

FIG. 2 is a view illustrating a jig supplying method of a power module manufacturing system 1 according to an exemplary embodiment of the present disclosure.

Referring to FIG. 2, the process controller 200 of the power module manufacturing system 1 may receive the supplying jig information for manufacturing the power module (S200). Herein, the supplying jig information may include a lot number of the jig supplied for manufacturing the power module.

Thereafter, the process controller 200 may compare the previously calculated abnormality index information per jig with the received supplying jig information (S210).

Herein, the abnormality index information per jig may include the jig lot number and the abnormality index. For example, the abnormality index information per jig may be in a state of being sorted in descending or ascending order based on the abnormality index.

In the S210 step, the process controller 200 may determine the abnormality index, corresponding to the jig lot number included in the supplying jig information, in the abnormality index information per jig.

Thereafter, the process controller 200 may determine whether the abnormality index corresponding to the supplying jig information satisfies the supply permitting condition based on the comparison in the S210 step (S220).

In the S220 step, the process controller 200 may determine that the supply permitting condition is satisfied when the abnormality index corresponding to the supplying jig information is less than or equal to the preset abnormality threshold value.

In the S220 step, the process controller 200 can determine that the supply permitting condition is satisfied when the abnormality index corresponding to the supplying jig information is within the preset rank based on the abnormality index information per jig sorted in descending or ascending order.

Thereafter, when the abnormality index corresponding to the supplying jig information satisfies the supply permitting condition (S220-Yes), the process controller 200 may determine the jig corresponding to the supplying jig information as the suppliable jig and then supply the corresponding jig to the manufacturing process of the power module (S230).

When the abnormality index corresponding to the supplying jig information does not satisfy the supply permitting condition (S220-No), the process controller 200 may determine the jig corresponding to the supplying jig information as the non-suppliable jig and then block the supply of the corresponding jig (S240).

According to an exemplary embodiment, the process controller 200 may output information on the non-suppliable jig through the user interface 240 (S250).

According to an exemplary embodiment, the process controller 200 may output information on the suppliable jig through the user interface 240 based on the abnormality index information per jig sorted in descending or ascending order (S260).

In the S260 step, the process controller 200 may determine the jig information having the abnormality index less than or equal to the preset abnormality threshold value in the abnormality index information per jig, and may output the jig information having the abnormality index less than or equal to the preset abnormality threshold value.

In the S260 step, the process controller 200 may output the jig information where the abnormality index is within the preset rank based on the abnormality index information per jig sorted in descending or ascending order.

According to an exemplary embodiment, the steps S250 and S260 may not be performed. According to an exemplary embodiment, only one of the steps S250 and S260 may be performed.

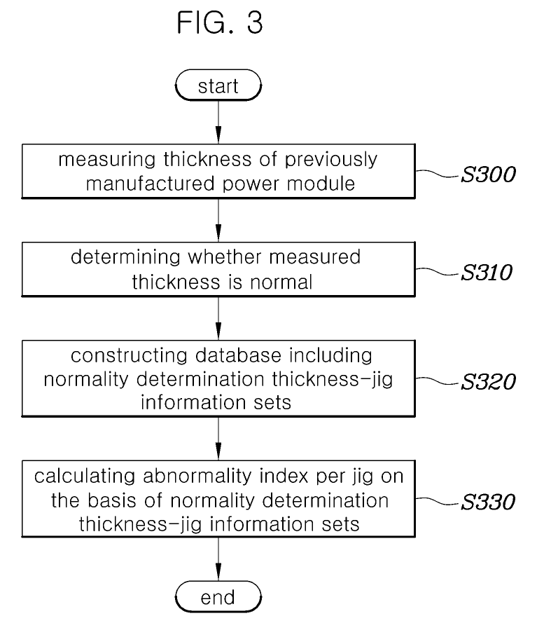

FIG. 3 is a view illustrating a method of calculating an abnormality index per jig in a power module manufacturing system 1 according to an exemplary embodiment of the present disclosure.

Referring to FIG. 3, the analyzer 100 of the power module manufacturing system 1 may measure the thickness of the previously manufactured power module by using the jig (S300).

In the S300 step, the analyzer 100 may measure the thickness of the plurality of previously manufactured power modules by using one jig. One jig may be supplied multiple times within a certain period of time to manufacture the power module.

In the S300 step, the analyzer 100 may measure the thickness of the previously manufactured power module with respect to the preset position. For example, the analyzer device 100 may measure the thickness with respect to the plurality of preset positions for one power module.

Thereafter, the analyzer 100 may determine whether the measured thickness is normal (S310).

In the S310 step, the analyzer 100 may compare the measured thickness with the reference range per position, and determine that the measured thickness is normal when the measured thickness is within the reference range.

In the S310 step, the analyzer 100 may construct a database by matching the thickness determined to be normal (the normality determination thickness) and the jig information (e.g., the jig lot number) used to manufacture the corresponding power module and storing the same in the storage 120 (S320).

That is, the analyzer 100 may match the normality determination thickness and the jig information and store the same in the storage 120. The jig information matched with the normality determination thickness may be referred to as normality determination jig information.

According to an exemplary embodiment, one jig may be used to manufacture the plurality of power modules, and the thickness may be measured at the plurality of positions for one power module. Therefore, the thickness data measured at the plurality of positions for each of the plurality of power modules may be matched with one normality determination jig information.

In addition, one jig may be supplied once or multiple times within a certain period of time to the manufacturing process of the power module.

Accordingly, the database may be constructed to include a plurality of normality determination thickness-jig information sets.

In this case, the normality determination thickness-jig information set may include a plurality of thickness data related to one jig. According to an exemplary embodiment, the database may include one normality determination thickness-jig information set related to one jig or include a plurality of normality determination thickness-jig information sets related to one jig.

Thereafter, the analyzer 100 may calculate the abnormality index per jig based on the normality determination thickness-jig information sets stored in the database (S330).

According to an exemplary embodiment, the analyzer 100 may calculate the abnormality index per jig based on the training with respect to the normality determination thickness in the database.

For example, the analyzer 100 may be trained with the normality determination thickness based on the unsupervised learning algorithm, a Gaussian mixture model (GMM).

For example, the analyzer 100 may model the normality determination thickness as a Gaussian distribution, extract the average and covariance from the Gaussian distribution, calculate the Mahalanobis distance for the thickness based on the average and covariance, and calculate the abnormality index based on the Mahalanobis distance.

According to an exemplary embodiment, when the plurality of normality determination thickness-jig information sets related to one jig are stored in the database, the analyzer 100 may calculate the abnormality index average by averaging the abnormality index calculated for each of the plurality of normality determination thickness-jig information sets related to one jig.

Although the exemplary embodiments of the present disclosure have been described in more detail with reference to the accompanying drawings, the present disclosure is not necessarily limited to these exemplary embodiments, and may be variously modified without departing from the technical idea of the present disclosure. Accordingly, the exemplary embodiments disclosed in the present specification may not be intended to limit the technical idea of the present disclosure but to illustrate the technical idea of the present disclosure, and the scope of the technical idea of the present disclosure may not be limited by these exemplary embodiments. Therefore, it should be understood that the exemplary embodiments described above are exemplary and not limited in all respects. The scope of protection of the present disclosure should be interpreted by the scope of claims, and all technical ideas within the equivalent scope should be construed as being included in the scope of the rights of the present disclosure.

What is claimed is:

1. A power module manufacturing system, the system comprising:
an analyzer configured to calculate abnormality index information per jig based on a normality determination thickness measured with respect to a power module previously manufactured using a jig; and
a process controller configured to receive jig information corresponding to information about the jig supplied for manufacturing a new power module, determine an abnormality index corresponding to the jig information based on the abnormality index information per jig, and supply the jig corresponding to the jig information to a manufacturing process of the new power module based on that the abnormality index satisfies a preset supply permitting condition.

2. The system of claim 1, wherein the analyzer is further configured to generate a normality determination thickness-jig information set by matching the jig information used to manufacture the previously manufactured power module with the normality determination thickness, and calculate the abnormality index information per jig based on the normality determination thickness-jig information set.

3. The system of claim 1, wherein the analyzer is further configured to calculate the abnormality index information per jig based on a training with the normality determination thickness.

4. The system of claim 1, wherein the process controller is further configured to determine that the supply permitting condition is satisfied based on that the abnormality index is less than or equal to a preset abnormality threshold value.

5. The system of claim 1, wherein the abnormality index information per jig is sorted in descending or ascending order, and the process controller is further configured to determine that the supply permitting condition is satisfied based on that the abnormality index corresponding to the jig information is determined to be within a preset rank.

6. The system of claim 1, wherein the process controller is further configured to block the supply of the corresponding jig based on that the abnormality index does not satisfy the preset supply permitting condition.

7. The system of claim 6, wherein the process controller is further configured to output information on a non-suppliable jig through a user interface.

8. The system of claim 6, wherein the process controller is further configured to output information on a suppliable jig through a user interface based on the abnormality index information per jig sorted in descending or ascending order.

9. A jig supplying method of a power module manufacturing system, the method comprising:
calculating, by a processor, abnormality index information per jig based on a normality determination thickness measured with respect to a power module previously manufactured using a jig;
receiving, by the processor, jig information corresponding to information about the jig supplied for manufacturing a new power module;
determining, by the processor, an abnormality index corresponding to the jig information based on the abnormality index information per jig; and
supplying, by the processor, the jig corresponding to the jig information to a manufacturing process of the new power module based on that the abnormality index satisfies a preset supply permitting condition.

10. The method of claim 9, wherein the calculating comprises generating a normality determination thickness-jig information set by matching the jig information used to manufacture the previously manufactured power module with the normality determination thickness, and calculating the abnormality index information per jig based on the normality determination thickness-jig information set.

11. The method of claim 9, wherein the calculating comprises calculating the abnormality index information per jig based on a training with the normality determination thickness.

12. The method of claim 9, wherein the supply permitting condition is satisfied in the supplying based on that the abnormality index is less than or equal to a preset abnormality threshold value.

13. The method of claim 9, wherein the abnormality index information per jig is sorted in descending or ascending order, and the supply permitting condition is satisfied in the supplying based on that the abnormality index is within a preset rank.

14. The method of claim 9, further including:
blocking, by the process controller, the supply of the corresponding jig based on that the abnormality index does not satisfy the preset supply permitting condition.

15. The method of claim 14, further including: outputting, by the process controller, information on a non-suppliable jig through a user interface.

16. The method of claim 14, further including:
outputting, by the process controller, information on a suppliable jig through a user interface based on the abnormality index information per jig sorted in descending or ascending order.

17. A non-transitory computer readable storage medium on which a program for performing the method of claim 9 is recorded.
